(19) United States
(12) Patent Application Publication
(10) Pub. No.: US 2013/0257447 A1
(43) Pub. Date: Oct. 3, 2013

(54) PORTABLE ELECTRONIC DEVICE

(71) Applicants: Osamu Kitaura, Kanagawa (JP); Toshinori Fukasawa, Kanagawa (JP)

(72) Inventors: Osamu Kitaura, Kanagawa (JP); Toshinori Fukasawa, Kanagawa (JP)

(73) Assignee: PANASONIC CORPORATION, Osaka (JP)

(21) Appl. No.: 13/992,006

(22) PCT Filed: Dec. 14, 2011
(86) PCT No.: PCT/JP2011/006988

§ 371 Date: Jun. 6, 2013

(30) Foreign Application Priority Data
Dec. 16, 2010 (JP) 2010-280142

(51) Int. Cl. G01R 31/02

(52) U.S. Cl. CPC G01R 31/02
USPC 324/537

(57) ABSTRACT

A portable electronic device includes a functional section that operates in first and second modes, a current measurement section that measures a current supplied to the functional section, and an abnormality detection section that confirms the current in a first cycle, a second cycle, or a third cycle, and detects current abnormality. When the functional section operates in the first mode, the abnormality detection section confirms the current in the first cycle, next, when the functional section is switched from the first mode to the second mode, the abnormality detection section confirms the current in the second cycle, and when the abnormality detection section does not detect the current abnormality for a predetermined period after the mode has been switched, the abnormality detection section confirms the current in the third cycle.

### TECHNICAL FIELD

The present invention relates to an abnormality detection circuit which prevents the progress of heat generation or breakdown due to an overcurrent caused by breakdown or the like of an electronic circuit in a portable electronic device, and a portable electronic device including the abnormality detection circuit.

### BACKGROUND ART

There is a case where an overcurrent flows in a circuit of a portable electronic device due to abnormality, such as breakdown or control failure of an electronic circuit in a portable electronic device, causing harmful heat generation. However, if the state is constantly monitored using any abnormality detection circuit so as to detect abnormality, power consumption increases with the operation of the abnormality detection circuit.

Examples of the related art which reduces power consumption in monitoring the state include a technique in which, in a mobile device which acquires a discharge current or performs an arithmetic operation in a predetermined sampling cycle, the sampling cycle is set to be short during power-on and to be long during power-off depending on the state of power-on/off of the device, thereby suppressing power consumption during power-off with little fluctuation in a current to be consumed (PTL 1); a technique in which, in the battery management of an electric vehicle, battery monitoring is performed in a short monitoring cycle during key switch-off the same as during key switch-on when there is a lot of fluctuation in the terminal voltage of the battery for a given period immediately after the key switch is off or when change in the terminal voltage is severe, and is performed in a longer monitoring cycle when the given period has elapsed or when change in the terminal voltage is gentle, thereby suppressing power consumption in the monitoring operation when the given period has elapsed (PTL 2); and the like.

In the previous devices, with these techniques, reduction in power consumption in monitoring the state of the current or the battery has been achieved.

### CITATION LIST

### Patent Literature

PTL 1: JP-A-2008-278745

PTL 2: JP-A-8-140208

### SUMMARY OF THE INVENTION

### Problems to be Solved by the Invention

It is very important that the abnormality detection circuit of the portable electronic device has high precision and responsiveness of abnormality detection, and requires low power consumption for an abnormality detection operation.

In order to suppress power consumption, a configuration in which the abnormality detection operation is executed cyclically using a predetermined sampling cycle is considered. If the cycle is shortened, while responsiveness of abnormality detection is satisfactory, power consumption increases. To the contrary, if the cycle is extended, while responsiveness is not satisfactory, power consumption decreases. Since responsiveness of abnormality detection and power consumption are in a trade-off relationship, it is necessary to adjust the cycle taking this point into consideration.

In order to detect the occurrence of abnormality, such as breakdown, quickly with high precision, a determination criterion for abnormality detection may be switched depending on the operation state of the device, and a value obtained by adding a margin to a required current value in each operation state may be set as a determination criterion.

For example, in the abnormality detection circuit, when the maximum operating current of the device is 100%, and 105% obtained by adding a margin of 5% is set as an abnormality determination criterion, it is not possible to determine an abnormality if a current at the time of the occurrence of breakdown does not exceed 105%. However, since breakdown of only a current corresponding to 5% of the maximum operating current continuously flowing may occur, the determination criterion for abnormality detection is switched depending on the operation state so as to increase determination precision.

As described above, in the case of breakdown of a current corresponding to 5% of the maximum operating current continuously flowing, when the determination criterion according to the operation state during the operation of the device is 105% or 50% or the like assuming a certain amount of current during the operation, there is a high possibility that abnormality may be buried beneath variation in a current, a margin of the determination criterion, or the like, and may not be detected. Meanwhile, if the determination criterion when the device is switched to a standby state is, for example, 3%, an abnormal current of 5% can be detected.

Breakdown may occur in a circuit which is used only in a specific operation state. In the case of breakdown of an overcurrent flowing only when power is supplied to the circuit, abnormality is not detected when the circuit is not used. If the operation state is switched and the circuit is used, an overcurrent flows in a broken location, and abnormality is likely to be detected. That is, breakdown is easily detected when switching the operation state.

From the above, it is considered that, if the cycle of sampling of abnormality detection is shortened after switching the operation state of the device, responsiveness of abnormality detection is improved.

However, in the related art, since the sampling cycle during power-off is extended under given conditions so as to achieve reduction in power, reduction in power is possible only during power-off. If the sampling cycle during power-off is extended, there is a problem in that responsiveness of abnormality detection after switching to power-off is deteriorated.

### Means for Solving the Problems

A portable electronic device of the invention includes a functional section that operates in a first mode and a second mode, a current measurement section that measures a current supplied to the functional section, and an abnormality detection section that confirms the current in a first cycle, a second cycle shorter than the first cycle, or a third cycle longer than the second cycle, and detects current abnormality, in which, when the functional section operates in the first mode, the abnormality detection section confirms the current in the first cycle, next, when the functional section is switched from the first mode to the second mode, the abnormality detection section confirms the current in the second cycle, and when the abnormality detection section does not detect the current abnormality for a predetermined period after the mode has been switched, the abnormality detection section confirms the current in the third cycle.

According to this configuration, after the mode has been switched, the current is confirmed in the second cycle shorter than the first cycle before the mode is switched, whereby it is possible to increase responsiveness with respect to abnormality which can be detected after the mode has been switched. Furthermore, when the current abnormality is not detected for the predetermined period, since the current is confirmed in the third cycle longer than the second cycle, it is possible to reduce power consumption required for abnormality detection.

In the portable electronic device of the invention, when the abnormality detection section detects the current abnormality for the predetermined period after the mode has been switched, the abnormality detection section continuously confirms the current in the second cycle.

According to this configuration, when the current abnormality is detected for the predetermined period after the mode has been switched, since the second cycle shorter than the first cycle and the third cycle is maintained, it is possible to maintain a state of high responsiveness with respect to abnormality and to monitor the subsequent progress of abnormality more closely.

In the portable electronic device of the invention, the predetermined period is set to a first period, after the abnormality detection section detects the current abnormality for the first period after the mode has been switched, the abnormality detection section continuously confirms the current in the second cycle, and thereafter, when the abnormality detection section does not continue to detect the current abnormality for a second period or more, the abnormality detection section confirms the current in the third cycle.

According to this configuration, when there is abnormality for the first period after the mode has been switched, and the second cycle is continued even after the first period has elapsed, since it is confirmed that abnormality is returned to normal, and the current is confirmed in the third cycle longer than the second cycle, it is possible to reduce power consumption required for abnormality detection.

In the portable electronic device of the invention, the functional section is switched from the first mode to the second mode based on power-on or off of the portable electronic device.

According to this configuration, it is possible to increase responsiveness with respect to abnormality after the portable electronic device is switched from power-on to power-off or from power-off to power-on, and to reduce power consumption required for abnormality detection.

In the portable electronic device of the invention, the functional section includes at least one of a display section, a camera section, a voice input and output section, and a network connection section, and the functional section is switched from the first mode to the second mode based on a change in the operation state of each of the display section, the camera section, the voice input and output section, and the network connection section.

According to this configuration, it is possible to increase responsiveness with respect to change in the operation states of the display section, the camera section, the voice input and output section, and the network connection section in the functional section, and to reduce power consumption required for abnormality detection.

In the portable electronic device of the invention, the current abnormality has a current larger than a predetermined threshold value.

According to this configuration, when an overcurrent is generated due to breakdown or the like of a circuit constituting the portable electronic device, it is possible to detect current abnormality.

The portable electronic device of the invention further includes a switch configured to limit the current to be supplied the functional section, in which, when the abnormality detection section detects the current abnormality, the current is limited by the switch.

According to this configuration, when the abnormality detection section detects the current abnormality, the current is limited by the switch, thereby suppressing the progress of heat generation or breakdown.

In the portable electronic device of the invention, the functional section operates in a third mode, in which current consumption is lower than in the second mode, in addition to the first and second modes, and when the abnormality detection section detects the current abnormality, the functional section is switched to the third mode.

According to this configuration, when the abnormality detection section detects the current abnormality, the functional section is switched to the third mode in which current consumption is low, thereby decreasing the current flowing in the functional section and suppressing the progress of heat generation or breakdown.

In the portable electronic device of the invention, the functional section includes a display section and/or a sound output section, and when the abnormality detection section detects the current abnormality, the display section and/or the sound output section reports abnormality.

According to this configuration, when the abnormality detection section detects the current abnormality, abnormality is reported by the display section and/or the sound output section, thereby getting the attention of the user.

The portable electronic device of the invention further includes an abnormal state storage section that, when the abnormality detection section detects the current abnormality, stores a state of the current abnormality along with the date and time.

According to this configuration, when a manufacturer or the like analyzes failure, the state of the current abnormality and the occurrence date and time can be read from the abnormal state storage section, thereby improving analysis efficiency.

The portable electronic device of the invention further includes a battery, in which the current supplied to the functional section is supplied from the battery.

According to this configuration, when the current abnormality is not detected for the predetermined period after the mode has been switched, the current is confirmed in the third cycle longer than the second cycle, since it is possible to reduce power consumption required for abnormality detection, it is possible to extend the driving time of the portable electronic device by the battery.

An abnormality detection circuit for a portable electronic device of the invention includes a mode input section that is connectable to an external functional section operating in a first mode and a second mode and a current measurement section measuring a current supplied to the functional section and to which a state of a mode is input from the functional section, a current input section to which a current value measured by the current measurement section is input, and an abnormality detection section that confirms the current in a first cycle, a second cycle shorter than the first cycle, or a third cycle longer than the second cycle, and detects current abnormality, in which, when the functional section operates in the first mode, the abnormality detection section confirms the current in the first cycle, next, when the functional section is switched from the first mode to the second mode, the abnormality detection section confirms the current in the second cycle, and when the abnormality detection section does not detect the current abnormality for a predetermined period after the mode has been switched, the abnormality detection section confirms the current in the third cycle.

According to this configuration, if the switching of the mode is input from the external functional section by the mode input section, since the current is confirmed in the second cycle shorter than the first cycle before the mode is switched, it is possible to increase responsiveness with respect to abnormality which can be detected after the mode has been switched. When the current abnormality is not detected for the predetermined period, since the current is confirmed in the third cycle longer than the second cycle, it is possible to reduce power consumption required for abnormality detection.

A portable electronic device of the invention includes a functional section that operates in a first mode and a second mode, a current measurement section that measures a current supplied to the functional section, and an abnormality detection section that confirms the current in a first cycle or a second cycle shorter than the first cycle, and when the current has a value equal to or greater than a predetermined value, detects current abnormality, in which, when the functional section operates in the first mode, the abnormality detection section confirms the current in the first cycle, and next, when the functional section is switched from the first mode to the second mode, the abnormality detection section confirms the current in the second cycle.

According to this configuration, since the current is confirmed in the second cycle shorter than the first cycle before the mode is switched after the mode has been switched, it is possible to increase responsiveness with respect to abnormality which can be detected after the mode has been switched.

### Advantageous Effects of the Invention

According to the portable electronic device and the abnormality detection circuit of the invention, it is possible to increase responsiveness with respect to current abnormality after the function mode of the portable electronic device has been switched and thus to detect abnormality quickly. When the current abnormality is not detected for a given period after the function mode has been switched, it is possible to reduce power consumption required for detecting current abnormality.

When the current abnormality is detected, it is possible to limit the current so as to prevent the progress of heat generation or breakdown, to get the attention of the user or to store the details of abnormality, to increase safety of the portable electronic device, and to increase workability for failure analysis of the manufacturer.

### BRIEF DESCRIPTION OF THE DRAWINGS

FIG. 1 is a block diagram showing a configuration example of a portable electronic device according to an embodiment of the invention.

FIG. 2 is a block diagram showing an abnormality detection circuit in a configuration example of a portable electronic device according to an embodiment of the invention.

### DESCRIPTION OF EMBODIMENTS

Hereinafter, a portable electronic device and an abnomiality detection circuit according to an embodiment of the invention will be described referring to the drawings.

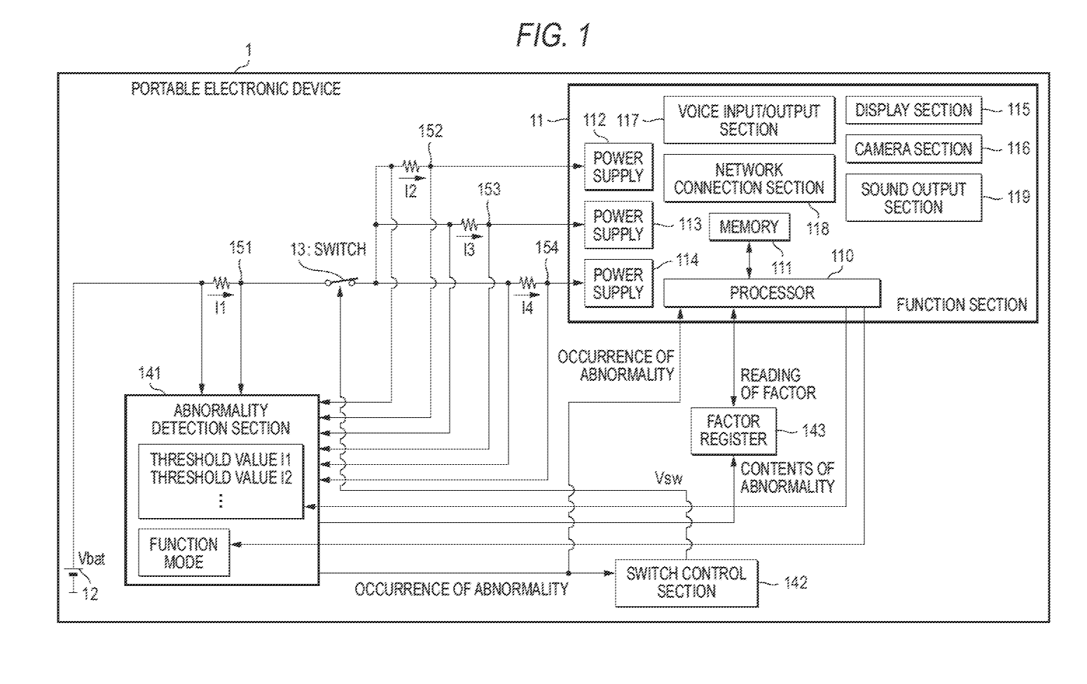

FIG. 1 is a block diagram showing a configuration example of a portable electronic device according to an embodiment of the invention.

A portable electronic device 1 includes a functional section 11, a battery 12, a switch 13, an abnormality detection section 141, a switch control section 142, a factor register 143, and a resistor 15n (where n=1 to 4).

The functional section 11 includes a processor 110, a memory 111, a power supply 112, a power supply 113, a power supply 114, a display section 1.5 115, a camera section 116, a voice input/output section 117, a network connection section 118, a sound output section 119, and the like, and executes various functions of the portable electronic device. The connection of the processor 110 and each component in the functional section 11 will be omitted.

The processor 110 performs the execution of various functions in the portable electronic device and overall control of peripheral components by software arranged in the memory 111.

The memory 111 performs the storage of software to be executed by the processor 110, data, and the like.

The power supplies 112, 113, and 114 supplies, to the respective components constituting the portable electronic device 1, such as the processor 110, the memory 111, and other circuits in the functional section 11, power converted to voltages appropriate for the specifications of the respective components on the basis of power Vbat to be supplied from the battery 12. Each of the power supplies 112, 113, and 114 may be constituted by a single power LSI or may be constituted using a single component, such as a LDO or a DC/DC converter. The number of power supplies is not particularly limited to three, and it should suffice that power required for each component constituting the portable electronic device is supplied without excess and deficiency. The power supply paths from the power supplies 112, 113, and 114 to the respective components will be omitted.

The display section 115 is constituted by liquid crystal or the like, and displays information, such as characters or figures, to the user. The camera section 116 is constituted by a lens, an imaging sensor, or the like, and performs imaging in accordance with a user operation. The voice input/output section 117 is constituted by a microphone, a receiver, or the like, and performs input/output of voice during a call or the like. The network connection section 118 is constituted by an antenna or a radio circuit and a circuit for transmission control or the like, and performs connection to a network. The sound output section 119 is constituted by a speaker or the like, and notifies the user of an incoming call or the like.

The battery 12 supplies power which is required for the portable electronic device 1.

The switch 13 is arranged on the power supply path between the battery 12 and the functional section 11 including the processor 110, and limits power Vbat to be supplied to the functional section 11 or the like from the battery 12 in accordance with a voltage Vsw to be output from the switch control section 142. The switch 13 may be an element whose resistance value changes depending on the voltage Vsw, and may be constituted using a MOSFET or the like.

The resistor 15n serves as a current measurement section and is arranged on the power supply path between the battery 12 and the functional section 11 including the processor 110. Although in this embodiment, four resistors are provided, the number of resistors is not necessarily four, and may increase or decrease depending on the number of current paths in which a current will be measured.

The abnormality detection section 141 compares a current value VIn obtained by amplifying a potential difference across both ends of the resistor 15n serving as a current measurement section with a threshold value In corresponding to the resistor 15n, when the current value exceeds the threshold value, determines that an abnormal current is detected by the resistor 15n, notifies the switch control section 142 and the processor 110 of the occurrence of abnormality, and notifies the factor register 143 of the details of abnormality. The threshold value In may be fixed, may be set from the processor 110, or may be switched depending on a function mode notified from the processor 110. When the threshold value In is fixed, a value which is slightly larger than a current normally flowing on the power supply path with the resistor 15n arranged thereon, a current value which is considered to be likely to accelerate the progress of breakdown when continuing, or the like is set. When the threshold value In is set from the processor 110 or is switched depending on the function mode, a value obtained by adding a margin to a required current value may be set depending on use circumstances at this time. The determination on the detection of an abnormal current may be made using multiple comparison results such that it is determined to be abnormality, for example, if the current value VIn exceeds the threshold value In three times in a row, thereby suppressing the effect of noise or temporary change in a current.

The abnormality detection section 141 performs the acquisition and comparison operation of the current value VIn or the like in a cycle according to the switching state of the function mode notified from the processor 110 and the presence/absence of the detection of the abnormal current, instead of constantly comparing the current value VIn with the threshold value In. Here, the abnormality detection section 141 is configured to set three or more cycles, uses a first cycle before the switching of the function mode is notified from the processor 110, operates using a second cycle shorter than the first cycle for a given time after the switching of the function mode is notified, when abnormality is detected in the interim, maintains the second cycle afterward, and if abnormality is not detected, uses a third cycle longer than the second cycle.

When abnormality is determined for a given time after the function mode has been switched, and the second cycle is maintained afterward, if abnormality is not determined for a given time or more, it may be determined to be a normal state, and the third cycle may be used. When it is determined that abnormality is returned to normal, the effect may be notified to the switch control section 142, the processor 110, and the like.

The abnormality detection section 141 may be configured to set two cycles, and may perform the acquisition and comparison operation of the current value using a fourth cycle before the switching of the function mode is notified from the processor 110 and using a fifth cycle shorter than the fourth cycle after the switching has been notified.

As the function mode, the power-on/off state of the device may be used, or the operation state of the display section 115, the camera section 116, the voice input/output section 117, the network connection section 118, the sound output section 119, or the like in the functional section 11 may be used. The function mode may be output from the display section 115, the camera section 116, the voice input/output section 117, the network connection section 118, the sound output section 119, or the like in the functional section 11 instead of the processor 110.

The switch control section 142 is notified of the occurrence of abnormality from the abnormality detection section 141, and controls the voltage Vsw to change the resistance value of the switch 13. The resistance value of the switch 13 is adjusted to limit power to be supplied to the functional section 11 including the processor 110, and the value is set so as to limit a current flowing to a location where abnormality occurs and suppress heat generation. While no abnormality occurs, the voltage Vsw is controlled such that the resistance value of the switch 13 is in the lowest state.

The switch control section 142 may be configured to provide a given delay time such that the time for which the processor 110 gets the attention of the user or performs processing for stopping the functions or processing for storing the details of abnormality can be secured until the current is limited by the switch 13 after the occurrence of abnormality is received.

The factor register 143 is notified of the details of abnormality from the abnormality detection section 141 when abnormality occurs and stores the details. The factor register 143 is configured to be connected to the processor 110 such that the details of abnormality can be read.

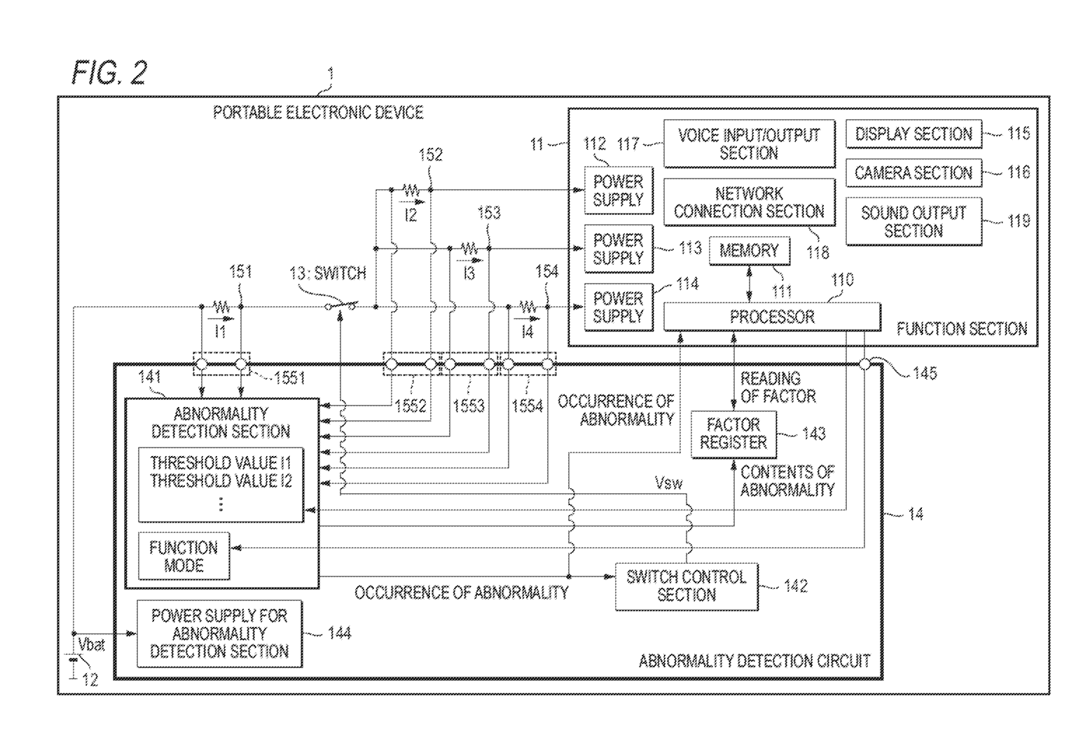

Although all or some of the abnormality detection section 141, the switch control section 142, and the factor register 143 are configured to be processed by software which is operated by the processor 110, as shown in FIG. 2, the abnormality detection circuit 14 may be configured to include the abnormality detection section 141, the switch control section 142, the factor register 143, a power supply 144 for abnormality detection section, a mode input section 145, and a current input section 155n (where n=1 to 4), and may be supplied with power between the battery 12 and the switch 13.

The power supply 144 for abnormality detection section supplies a voltage appropriate for each circuit in the abnormality detection circuit 14.

The mode input section 145 receives an input of the state of the function mode from the processor 110 in the functional section 11 and outputs the function mode to the abnormality detection section.

The current input section 155n receives an input of the current value from the resistor 15n, and outputs the current value to the abnormality detection section.

The abnormality detection circuit 14 may be integrated as an LSI.

Next, the details of an operation example of the portable electronic device 1 of FIG. 1 will be described.

As the operation example to be described, a case where a camera function changes from off to on will be described as the switching of the function mode. It is assumed that the operation cycle of the acquisition of the current value and the comparison with the threshold value of the abnormality detection section 141 is 160 [ms] when the camera function is off before switching, 40 [ms], for a given period after switching, and is then 160 [ms] when the determination result for the given period is normal. It is also assumed that the given period is 320 [ms].

The power supply for the camera section 116 in the functional section 11 is the power supply 112, and in this operation example, it is assumed that a user operates a menu when the camera function is off, a current flowing in the resistor 152 is appropriately 150 [mA] to be consumed by circuits, to which the power supply 112 is connected, other than the camera section 116, and a threshold value I2 is set to 200 [mA] taking into consideration a margin, such as product variation or detection error. While the camera is being activated, it is assumed that the current flowing in the resistor 152 is appropriately 450 [mA] with the operating current 300 [mA] of the camera section 116 added thereto, and the threshold value I2 is set to 500 [mA] taking into consideration a margin, such as product variation or detection error.

Subsequently, the operation of the circuit when the function mode is switched (the camera function is switched from off to on) will be described in time series.

The abnormality detection section 141 performs an operation to acquire the current value VI2 from the resistor 152 and to compare with the threshold value I2 (=200 [mA]) in a cycle of 160 [ms] before the camera function is turned on by a user operation. The processor 110 receives a user operation from an operating section (not shown) and controls the camera section 116 to turn on the camera function, and also notifies the abnormality detection section 141 of the switching of the function mode. The abnormality detection section 141 receives the notification, switches the threshold value I2 to 500 [mA], and performs the acquisition of the current value VI2 and the comparison with the threshold value I2 (=500 [mA]) in a cycle of 40 [ms] for 320 [ms] after the notification is received.

A current of about 450 [mA] flows in the resistor 152 after the camera function is turned on, and when it is determined to be normal as the result of the comparison for 320 [ms] after the notification is received, the operation of the acquisition of the current value VI2 and the comparison with the I2 (=500 [mA]) is carried out in a cycle of 160 [ms] when 320 [ms] elapses after the notification is received.

To the contrary, a current of about 600 [mA] flows in the resistor 152 after the camera function is turned on, and when it is determined to be abnormal as the result of the comparison for 320 [ms] after the notification is received, the operation of the acquisition of the current value VI2 and the comparison with the threshold value I2 (=500 [mA]) is carried out in a cycle of 40 [ms] even when 320 [ms] elapses after the notification is received. The occurrence of abnormality is notified to the processor 110 and the switch control section 142, and an abnormal current flowing in the resistor 152 is notified to the factor register 143.

If the occurrence of abnormality is notified by interruption or the like, the processor 110 reports abnormality by the display section 115, the sound output section 119, and the like to get the attention of the user, reads the details of the factor register 143 to determine that an abnormal current is detected in the resistor 152, and performs processing for storing the details of abnormality for use in failure analysis, or the like. As information to be stored in the processing for storing the details of abnormality, information useful for subsequent failure analysis of the manufacturer, such as the location where abnormality occurs is the resistor 152, the occurrence date and time, and the used function (in the present example, when the camera function is turned on), may be used. As a storage destination, although a memory element dedicated for storing the abnormal state may be prepared, this causes an increase in cost, and thus a nonvolatile memory which is usually and generally provided in the portable electronic device is used, thereby suppressing an increase in cost.

The switch control section 142 is notified of the occurrence of abnormality, controls the voltage Vsw to increase the resistance value of the switch 13 and limit power to be supplied to the functional section 11, and sets the value so as to limit the current flowing to the location where abnormality occurs and suppress heat generation. For 0.5 [s] after the occurrence of abnormality is notified, the resistance value of the switch 13 is maintained at the same minimum resistance value as during normal use and the processing for storing the details of abnormality or the like is performed. After 0.5 [s] elapses, the voltage Vsw may be controlled and the switch 13 may have the maximum resistance value so as to shut off the current flowing in the functional section 11.

The occurrence of abnormality may be notified, each circuit in the functional section may be controlled by the processor 110, and the camera function may be turned off or the device may be switched to a state with low current consumption, such as a standby state or a power-off state, thereby suppressing the current of the device.

As described above, the current of about 600 [mA] flows in the resistor 152 after the camera function is turned on, and when it is determined to be abnormal as the result of the comparison for 320 [ms] after the notification is received, the operation of the acquisition of the current value VI2 and the comparison with the threshold value I2 (=500 [mA]) is carried out in a cycle of 40 [ms] even when 320 [ms] elapses after the notification is received. Meanwhile, when it is determined to be normal as the result of the operation of the acquisition of the current value VI2 and the comparison with the threshold value I2 (=500 [mA]) for a given period (for example, six times or more in a cycle of 40 [ms] for equal to or longer than 200 [ms]), the cycle may be changed to 160 [ms].

With the portable electronic device 1 and the abnormality detection circuit 14 according to the embodiment of the invention, since the cycle of the acquisition of the current value, the comparison with the threshold value, and the like is shortened after the function mode has been switched, it is possible to increase responsiveness with respect to current abnormality after switching and thus to detect abnormality quickly.

When current abnormality is not detected for a given period after switching, the cycle is extended, thereby reducing power consumption required for detecting current abnormality.

When current abnormality is detected, it is possible to limit the current by the switch so as to prevent the progress of heat generation or breakdown, to get the attention of the user or to store the details of abnormality, to increase safety of the portable electronic device, and to increase workability for failure analysis of the manufacturer.

Although the invention has been described in detail or referring to a specific embodiment, it is obvious to those skilled in the art that various alterations or corrections may be made without departing from the spirit and scope of the invention.

This application is based on Japanese Patent Application No. 2010-280142, filed on Dec. 16, 2010, the contents of which are incorporated herein by reference.

### INDUSTRIAL APPLICABILITY

The invention is useful as a portable electronic device, an abnormality detection circuit, or the like which detects an overcurrent due to breakdown or the like of an electronic circuit with low power consumption and high precision and responsiveness.

### DESCRIPTION OF REFERENCE NUMERALS AND SIGNS

1: portable electronic device

11: functional section

110: processor

111: memory

112: power supply

113: power supply

114: power supply

115: display section

116: camera section

117: voice input/output section

118: network connection section

119: sound output section

12: battery

13: switch

14: abnormality detection circuit

141: abnormality detection section

142: switch control section

143: factor register

144: power supply for abnormality detection section

145: mode input section

151: resistor for current detection

152: resistor for current detection

153: resistor for current detection

154: resistor for current detection

1551: current input section 1

1552: current input section 2

1553: current input section 3

1554: current input section 4

1. A portable electronic device comprising:
a functional section that operates in a first mode and a second mode;
a current measurement section that measures a current supplied to the functional section; and
an abnormality detection section that confirms the current in a first cycle, a second cycle shorter than the first cycle, or a third cycle longer than the second cycle, and detects current abnormality,
wherein, when the functional section operates in the first mode, the abnormality detection section confirms the current in the first cycle;
next, when the functional section is switched from the first mode to the second mode, the abnormality detection section confirms the current in the second cycle; and
when the abnormality detection section does not detect the current abnormality for a predetermined period after the mode has been switched, the abnormality detection section confirms the current in the third cycle; and
wherein the functional section is switched from the first mode to the second mode based on power-on or off of the portable electronic device.

2. The portable electronic device according to claim 1, wherein, when the abnormality detection section detects the current abnormality for the predetermined period after the mode has been switched, the abnormality detection section continuously confirms the current in the second cycle.

3. The portable electronic device according to claim 2, wherein the predetermined period is set to a first period;
after the abnormality detection section detects the current abnormality for the first period after the mode has been switched, the abnormality detection section continuously confirms the current in the second cycle; and
thereafter, when the abnormality detection section does not continuously detect the current abnormality for a second period or more, the abnormality detection section confirms the current in the third cycle.

4.-5. (canceled)

6. The portable electronic device according to claim 1, wherein the current abnormality has a current larger than a predetermined threshold value.

7. The portable electronic device according to claim 1, further comprising:
a switch configured to limit the current supplied to the functional section,
wherein, when the abnormality detection section detects the current abnormality, the current is limited by the switch.

8. The portable electronic device according to claim 1, wherein the functional section operates in a third mode, in which current consumption is lower than in the second mode, in addition to the first and second modes; and
wherein, when the abnormality detection section detects the current abnormality, the functional section is switched to the third mode.

9. The portable electronic device according to claim 1, wherein the functional section includes a display section and/or a sound output section; and
wherein, when the abnormality detection section detects the current abnormality, the display section and/or the sound output section reports abnormality.

10. The portable electronic device according to claim 1, further comprising:
an abnormal state storage section that, when the abnormality detection section detects the current abnormality, stores a state of the current abnormality along with the date and time.

11. The portable electronic device according to claim 1, further comprising:
a battery,
wherein the current supplied to the functional section is supplied from the battery.

12.-13. (canceled)

14. A portable electronic device comprising:
a functional section that operates in a first mode and a second mode;
a current measurement section that measures a current supplied to the functional section; and
an abnormality detection section that confirms the current in a first cycle, a second cycle shorter than the first cycle, or a third cycle longer than the second cycle, and detects current abnormality,
wherein, when the functional section operates in the first mode, the abnormality detection section confirms the current in the first cycle;
next, when the functional section is switched from the first mode to the second mode, the abnormality detection section confirms the current in the second cycle; and
when the abnormality detection section does not detect the current abnormality for a predetermined period after the mode has been switched, the abnormality detection section confirms the current in the third cycle;
wherein the functional section includes at least one of a display section, a camera section, a voice input and output section, and a network connection section; and
wherein the functional section is switched from the first mode to the second mode based on change in a operation state of the at least one of the display section, the camera section, the voice input and output section, and the network connection section.

15. The portable electronic device according to claim 14, wherein, when the abnormality detection section detects the current abnormality for the predetermined period after the mode has been switched, the abnormality detection section continuously confirms the current in the second cycle.

16. The portable electronic device according to claim 15, wherein the predetermined period is set to a first period;
after the abnormality detection section detects the current abnormality for the first period after the mode has been switched, the abnormality detection section continuously confirms the current in the second cycle; and
thereafter, when the abnormality detection section does not continuously detect the current abnormality for a second period or more, the abnormality detection section confirms the current in the third cycle.

17. The portable electronic device according to claim 14, wherein the current abnormality has a current larger than a predetermined threshold value.

18. The portable electronic device according to claim 14, further comprising:
a switch configured to limit the current supplied to the functional section,
wherein, when the abnormality detection section detects the current abnormality, the current is limited by the switch.

19. The portable electronic device according to claim 14, wherein the functional section operates in a third mode, in which current consumption is lower than in the second mode, in addition to the first and second modes; and
wherein, when the abnormality detection section detects the current abnormality, the functional section is switched to the third mode.

20. The portable electronic device according to claim 14, wherein the functional section includes a display section and/or a sound output section; and
wherein, when the abnormality detection section detects the current abnormality, the display section and/or the sound output section reports abnormality.

21. The portable electronic device according to claim 14, further comprising:
an abnormal state storage section that, when the abnormality detection section detects the current abnormality, stores a state of the current abnormality along with the date and time.

22. The portable electronic device according to claim 14, further comprising:
a battery,
wherein the current supplied to the functional section is supplied from the battery.
